(19) United States
(12) Patent Application Publication
(10) Pub. No.: US 2013/0228757 A1
(43) Pub. Date: Sep. 5, 2013

(54) SERIES-CONNECTED ORGANIC ELECTROLUMINESCENT MODULE AND DISPLAY DEVICE INCLUDING THE SAME

(71) Applicant: INNOLUX CORPORATION, Miao-Li County (TW)

(72) Inventors: Hsin-Yuan SU, Miao-Li County (TW); Chun-Kai LI, Miao-Li County (TW); Hsiang-Lun HSU, Miao-Li County (TW)

(73) Assignee: INNOLUX CORPORATION, Miao-Li County (TW)

(21) Appl. No.: 13/775,288

(22) Filed: Feb. 25, 2013

(30) Foreign Application Priority Data
Mar. 2, 2012 (TW) 101106951

(51) Int. Cl. H01L 27/32

(52) U.S. Cl. CPC H01L 27/3204
USPC 257/40

(57) ABSTRACT

A series-connected organic electroluminescent module includes: a plurality of electroluminescent bodies each including an organic light-emitting layer; at least one charge-generating body capable of generating holes and electrons while being irradiated, and disposed to connect respective adjacent two of the electroluminescent bodies so as to form a series-connection of the electroluminescent bodies and the charge-generating body; and an electrode unit including an anode and a cathode that are respectively electrically connected to two outermost ones of the electroluminescent bodies disposed at two opposite terminals of the series-connection of the electroluminescent bodies and the at least one charge-generating body.

### CROSS-REFERENCE TO RELATED APPLICATION

This application claims priority of Taiwanese application no. 101106951, filed on Mar. 2, 2012.

### BACKGROUND OF THE INVENTION

1. Field of the Invention

This invention relates to an organic electroluminescent module, and more particularly to a series-connected organic electroluminescent module and a display device including the same.

2. Description of the Related Art

An organic electroluminescence device (OELD), also referred as an organic light emitting diode (OLED), is a solid state element, and has a better shock resistance compared to a presently-used liquid crystal display device. Furthermore, the OELD emits light by itself, and is different from the liquid crystal display device in which a backlight unit cooperates with the twist of liquid crystals to control a light luminance emitted from the liquid crystal display device. Accordingly, the OELD has a relatively large viewing angle, and would not have a problem of viewing angle limitations. Besides, the luminance of the OELD can be adjusted by the combination of carriers, and the OLED has a luminance response speed faster than that of the liquid crystal display device in which an equivalent liquid crystal capacitor is used to control the luminance thereof. Especially, the OLED can be formed on a soft flexible substrate. As such, the OELD has a better shock resistance, a wider viewing angle, a faster response speed and is flexible and light-weight, and thus has been applied for actual commercial use, such as lighting devices or displays.

Referring to FIG. 1, a conventional OLED comprises a transparent glass substrate 11, an anode 12 formed on the glass substrate 11, an electroluminescent body 14 formed on the anode 12, and a cathode 13 formed on the electroluminescent body 14. The electroluminescent body 14 is formed on the surface of the anode 12 by a hole injecting layer 141, a hole transporting layer 142, an organic light emitting layer 143, an electron transporting layer 144, and an electron injecting layer 145 in this order. Either one of the anode 12 and the cathode 13 is made of a transparent, light transmissive conductive material, for example, a very thin metal, a conductive oxide metal or a conductive polymer.

When an external direct current driving current source 15 is supplied to the anode 12 and the cathode 13, holes from the anode 12 are introduced into the hole injecting layer 141 of the electroluminescent body 14, and then moved to the organic light emitting layer 143 through the hole transporting layer 142. On the other hand, electrons from the cathode 13 are introduced into the electron injecting layer 145 of the electroluminescent body 14, and then moved to the organic light emitting layer 143 through the electron transporting layer 144. Next, the electrons and holes are recombined to become an excited state. Finally, the excited electron-hole pairs release the energy that turns into a light, and return to a ground state. The light passes through the electroluminescent body 14 and the surface of the cathode 13 or the anode 12 to be emitted externally.

However, such a conventional organic light emitting diode has a disadvantage in that only the electron-hole pairs from the anode 12 and the cathode 13 may be moved to the organic light emitting layer 143 and then recombined at the organic light emitting layer 143 to produce light, which causes the driving voltage of the conventional organic light emitting diode to be too high when a predetermined luminance is desired, or results in a lower luminance when a predetermined driving voltage is supplied.

Referring to FIG. 2, to overcome this disadvantage, in 2003, professor Junji Kido of Yamagata University in Japan disclosed a series-connected organic electroluminescent module that comprises a transparent glass substrate 21, an anode 22 formed on the glass substrate 21, two electroluminescent bodies 24 disposed on the anode 22, an intermediate connection body 25 disposed between the electroluminescent bodies 24, and a cathode 23 disposed on a top face of the electroluminescent bodies 24 distal from the glass substrate 21.

Similar to the electroluminescent body of the conventional organic light emitting diode, the electroluminescent bodies 24 comprise a hole injecting layer 241, a hole transporting layer 242, an organic light emitting layer 243, an electron transporting layer 244, and an electron injecting layer 245.

When an external direct current driving current source 26 is supplied to the anode 22 and the cathode 23, electron-hole pairs are formed in the intermediate connection body 25 as the intermediate connection body 25 is influenced by the electrical field generated by the direct current. Electrons in the intermediate connection body 25 are moved toward the anode 22 and injected into the organic light emitting layer 243 of the electroluminescent body 24 that is proximate to the anode 22, while holes in the intermediate connection body 25 are moved toward the cathode 23 and injected into the organic light emitting layer 243 of the electroluminescent body 24 that is proximate to the cathode 23. At this time, the holes supplied from the external direct current driving current source 26 are introduced into the hole injecting layer 241 of the electroluminescent body 24 that is proximate to the anode 22 through the anode 22, and then moved to the organic light emitting layer 243 through the hole transporting layer 242. On the other hand, the electrons supplied from the external direct current driving current source 26 are introduced into the electron injecting layer 245 of the electroluminescent body 24 that is proximate to the cathode 23 through the cathode 23, and then moved to the organic light emitting layer 243 through the electron transporting layer 244. Thus, the electrons formed in the intermediate connection body 25 and the holes from the external source are recombined at the organic light emitting layer 243 of the electroluminescent body 24 that is proximate to the anode 22 to emit light externally, while the holes formed in the intermediate connection body 25 and the electrons from the external source are recombined at the organic light emitting layer 243 of the electroluminescent body 24 that is proximate to the cathode 23 to emit light externally.

It is found that, in the abovementioned series-connected organic electroluminescent module, in addition to the electron-hole pairs from the anode 22 and the cathode 23, additional electron-hole pairs may be formed in the intermediate connection body 25 between the electroluminescent bodies 24 by virtue of the p-n junction principle, and then recombined in the organic light emitting layer 243 to emit light. Therefore, a doubled luminance may be obtained when the supplied direct current driving current is the same as that of the conventional organic light emitting diode, or a longer service life may be obtained as compared with the conventional organic light emitting diode when both produce a predetermined luminance. However, a higher driving voltage is required for the series-connected organic electroluminescent module.

Accordingly, there are many researches concerning the series-connected organic electroluminescent module, such as U.S. Pat. No. 7,728,517, U.S. Pat. No. 7,821,201, U.S. Pat. No. 7,968,217, etc., in which an n-type doped organic semiconductor layer in cooperation with a p-type doped organic semiconductor layer or a metal oxide layer serves as an intermediate connection body for generating electron-hole pairs as being influenced by the electrical field generated by the external electricity. Moreover, the series-connected organic electroluminescent module has become a main trend in developing the OLED, and thus, many efforts have focused on the development of the organic electroluminescent module that has lower driving voltage and higher luminance.

### SUMMARY OF THE INVENTION

Therefore, an object of the present invention is to provide a series-connected organic electroluminescent module with a lower driving voltage.

According to one aspect of this invention, a series-connected organic electroluminescent module comprises:

a plurality of electroluminescent bodies each including an organic light-emitting layer;

at least one charge-generating body capable of generating holes and electrons while being irradiated, and disposed to connect respective adjacent two of the electroluminescent bodies so as to form a series-connection of the electroluminescent bodies and the at least one charge-generating body; and

an electrode unit including an anode and a cathode that are respectively electrically connected to two outermost ones of the electroluminescent bodies which are respectively disposed on two opposite terminals of the series-connection of the electroluminescent bodies and the at least one charge-generating body.

According to another aspect of this invention, a series-connected organic electroluminescent module comprises:

a plurality of electroluminescent bodies each including an organic light-emitting layer capable of emitting light while receiving holes and electrons;

at least one charge-generating body including an n-type material layer and a p-type material layer, the charge-generating body being disposed to connect respective adjacent two of the electroluminescent bodies so as to form a series-connection of the electroluminescent bodies and the at least one charge-generating body, the n-type and p-type material layers being made of a material capable of absorbing visible light; and

an electrode unit including an anode and a cathode that are respectively electrically connected to two outermost ones of the electroluminescent bodies which are respectively disposed on two opposite terminals of the series-connection of the electroluminescent bodies and the at least one charge-generating body.

Preferably, the charge-generating body is capable of generating holes and electrons while receiving electricity.

The effect of this invention: The charge-generating body can generate holes and electrons not only while receiving electricity, but also while being irradiated by an external light or the light emitted from the electroluminescent bodies. The generated holes and electrons can be respectively provided to two adjacent electroluminescent bodies, thereby reducing driving voltage of the series-connected organic electroluminescent module.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic side view of a conventional organic light emitting diode;

FIG. 2 is a schematic side view of a conventional series-connected organic electroluminescent module;

FIG. 3 is a schematic side view of a first preferred embodiment of a series-connected organic electroluminescent module according to the present invention;

FIG. 4 is a schematic side view of a bottom emission type organic electroluminescent module of the first preferred embodiment;

FIG. 5 is a schematic side view of a reverse arranged bottom emission type organic electroluminescent module of the first preferred embodiment;

FIG. 6 is a schematic side view of a reverse arranged top emission type organic electroluminescent module of the first preferred embodiment;

FIG. 7 is a schematic side view of the series-connected organic electroluminescent module of the first preferred embodiment according to the present invention, in which a charge-generating body has a p-type material layer and an n-type material layer;

FIG. 8 is a schematic side view of a second preferred embodiment of a series-connected organic electroluminescent module according to the present invention;

FIG. 9 is a schematic side view of the second preferred embodiment of the series-connected organic electroluminescent module comprising a plurality of electroluminescent bodies and charge-generating bodies; and

FIG. 10 is a schematic side view of a third preferred embodiment of a series-connected organic electroluminescent module according to the present invention.

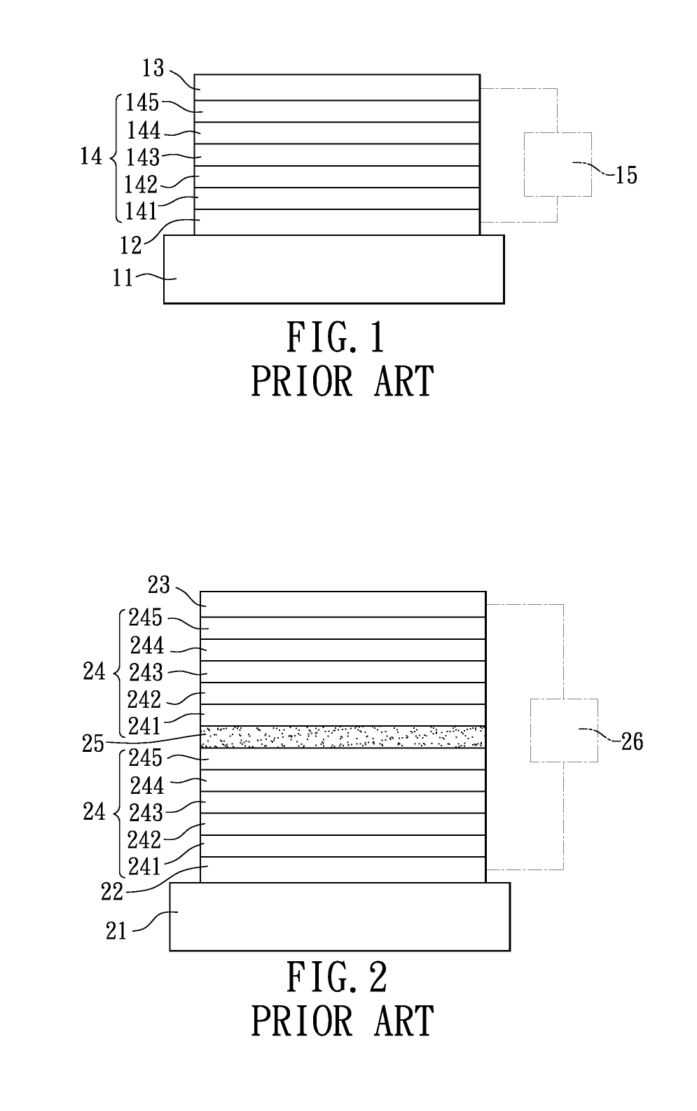

### DETAILED DESCRIPTION OF THE PREFERRED EMBODIMENTS

Before the present invention is described in greater detail, it should be noted herein that like elements are denoted by the same reference numerals throughout the disclosure.

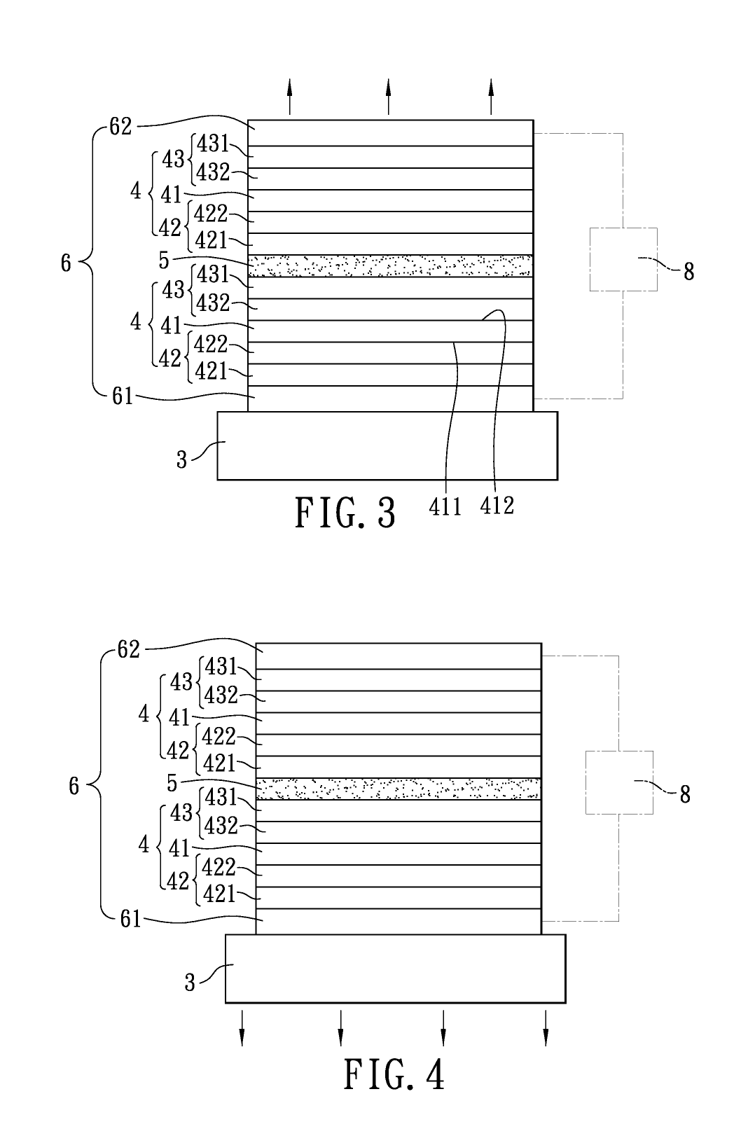

Referring to FIG. 3, a first preferred embodiment of a series-connected organic electroluminescent module according to the present invention comprises: a substrate structure 3, two electroluminescent bodies 4, a charge-generating body 5, and an electrode unit 6. The series-connected organic electroluminescent module of this invention is preferably used in a display device.

In the first preferred embodiment, the substrate structure 3 comprises a glass substrate or a flexible substrate, but is not limited thereto.

The electroluminescent bodies 4 are superimposed on the substrate structure 3. Each of the electroluminescent bodies 4 includes an organic light-emitting layer 41. The organic light-emitting layer 41 forms excited electron-hole pairs while receiving electrons and holes, and the electron-hole pairs return to a ground state after the energy is released to produce light. To transfer the electrons and holes more effectively to the organic light-emitting layer 41, each of the electroluminescent bodies 4 further includes a hole transporting unit 42 formed on and connected to a first surface 411 of the organic light-emitting layer 41, and an electron transporting unit 43 formed on and connected to a second surface 412 of the organic light-emitting layer 41 opposite to the first surface 411. The hole transporting unit 42 includes a hole transporting layer 422 connected to the organic light-emitting layer 41, and a hole injecting layer 421 connected to the hole transporting layer 422. The electron transporting unit 43 includes an electron transporting layer 432 formed on and connected to the organic light-emitting layer 41, and an electron injecting layer 431 formed on and connected to the electron transporting layer 432.

The hole transporting layer 422 of the hole transporting unit 42 is mainly made of NPB (N,N′-bis(naphthalen-1-yl)-N,N′-bis(phenyl)-benzidine), TPD (N,N′-bis(3-methylphenyl)-N,N′-bis(phenyl)-benzidine), or TAPC (Di-[4-(N,N-ditolyl-amino)-phenyl]cyclohexane). The electron injecting layer 431 of the electron transporting unit 43 is mainly made of lithium fluoride. The electron transporting layer 432 is mainly made of Alq₃ (Tris(8-hydroxy-quinolinato) aluminum), BPhen (4,7-diphenyl-1,10-phenanthroline), or BAlq (Bis(2-methyl-8-quinolinolate)-4-(phenylphenolato) aluminum). The organic light-emitting layer 41 is mainly made of an organic light emitting material that may be selected based on the wavelength range of a light to be emitted. For example, if a red light is to be emitted, the organic light emitting material may be mainly made of DCJTB (4-(dicyanomethylene)-2-tert-butyl-6-(1,1,7,7-tetramethyljulolidin-4-yl-vinyl)-4H-pyran). If a green light is to be emitted, the organic light emitting material may be mainly made of Alq₃ (Tris(8-hydroxy-quinolinato) aluminum). If a blue light is to be emitted, the organic light emitting material may be mainly made of DPVBi (4,4′-bis[4-(di-p-tolylamino)styryl]biphenyl). However, the materials of the organic light-emitting layer 41, the hole transporting unit 42, and the electron transporting unit 43 are not limited to the abovementioned materials, and other materials may be used for the hole transporting unit 42, the electron transporting unit 43 and the organic light-emitting layer 41 of the electroluminescent bodies 4 as long as the highest occupied molecular orbital (HOMO) of the hole transporting unit 42 and the lowest unoccupied molecular orbital (LUMO) of the electron transporting unit 43 may permit the electrons and holes to transit to the organic light-emitting layer 41 and generate light of a predetermined wavelength.

The charge-generating body 5 is disposed to connect between the electroluminescent bodies 4 so as to form a series-connection of the electroluminescent bodies 4 and the charge-generating body 5. The charge-generating body 5 is capable of generating holes and electrons while being irradiated. Preferably, the charge-generating body 5 is further capable of generating holes and electrons while receiving electricity.

The electrode unit 6 includes an anode 61 and a cathode 62 that are respectively electrically connected to the electroluminescent bodies 4 which are respectively disposed on two opposite terminals of the series-connection of the electroluminescent bodies 4 and the charge-generating body 5. More specifically, the anode 61 is electrically connected to the outermost layer of one of the electroluminescent bodies 4, i.e., the hole injecting layer 421, while the cathode 62 is electrically connected to the outermost layer of the other one of the electroluminescent bodies 4, i.e., the electron injecting layer 431.

In the present invention, the electroluminescent bodies 4 are light transmissible so that the charge-generating body 5 disposed between the electroluminescent bodies 4 can receive light energy. The substrate structure 3 comprises a glass substrate or a flexible substrate, but is not limited thereto. The substrate is made of transparent or opaque material.

When the charge-generating body 5 is irradiated, the charge-generating body 5 is excited to generate electron-hole pairs, wherein the electrons are moved toward the electroluminescent body 4 that is proximate to the anode 61, and then moved to the organic light-emitting layer 41 that is proximate to the anode 61 through the electron injecting layer 431 and the electron transporting layer 432 of the electroluminescent body 4, while the holes are moved toward the electroluminescent body 4 that is proximate to the cathode 62, and then moved to the organic light-emitting layer 41 that is proximate to the cathode 62 through the hole injecting layer 421 and the hole transporting layer 422 of the electroluminescent body 4. At this time, the holes from an external driving current source 8 are introduced into the hole injecting layer 421 of the electroluminescent body 4 that is proximate to the anode 61 through the anode 61, and then moved to the organic light-emitting layer 41 through the hole transporting layer 422. In addition, the electrons from the external driving current source 8 are introduced into the electron injecting layer 431 of the electroluminescent body 4 that is proximate to the cathode 62 through the cathode 62, and then moved to the organic light-emitting layer 41 through the electron transporting layer 432. Thus, the electrons formed in the charge-generating body 5 and the holes from an external source are recombined at the organic light emitting layer 41 of the electroluminescent body 4 that is proximate to the anode 61 to emit light externally, while the holes formed in the charge-generating body 5 and the electrons from the external source are recombined at the organic light emitting layer 41 of the electroluminescent body 4 that is proximate to the cathode 62 to emit light externally.

In addition, when the charge-generating body 5 in the first preferred embodiment is influenced by a current flowing through the electrode unit 6, electrons and holes are also generated by virtue of a potential difference, and similar to that described above, the electrons and holes may be introduced respectively into the adjacent electroluminescent bodies 4, thereby enabling the organic light-emitting layers 41 of the electroluminescent bodies 4 to emit light.

Further, when the electroluminescent bodies 4 emit light, the light emitted toward the charge-generating body 5 may excite the charge-generating body 5 to generate electrons and holes so that more electron-hole pairs may exist in the adjacent electroluminescent bodies 4.

In this preferred embodiment, the charge-generating body 5 may generate electrons and holes while receiving light and/or electricity, and does not need to completely rely on the electricity transferred through the electrode unit 6 to generate the electrons and holes. Therefore, in accordance with the present invention, consumption of electricity can be reduced, thereby effectively reducing the driving voltage of the organic electroluminescent module.

In this embodiment, the surface of the cathode 62 serves as a light-outputting surface. That is, the anode 61 is connected to the substrate structure 3 and the cathode 62 is a transparent electrode to form a top emission type organic electroluminescent module.

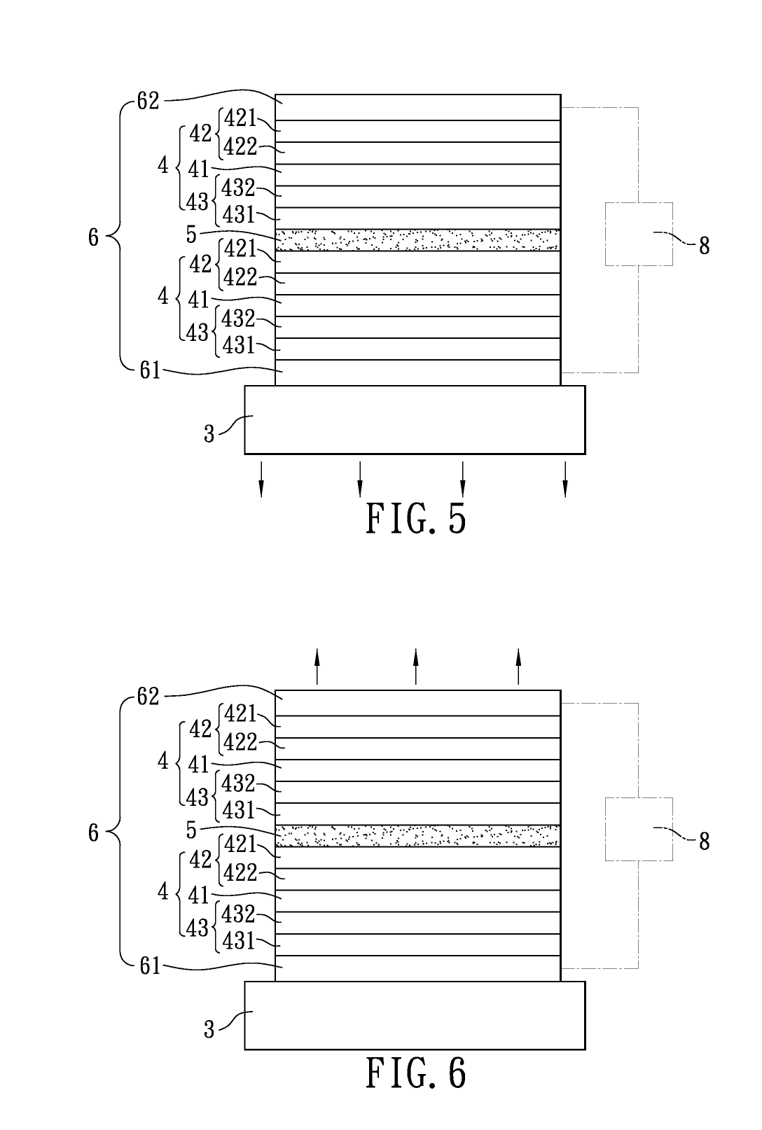

FIG. 4 illustrates another example of the first preferred embodiment of the series-connected organic electroluminescent module of the present invention. In this example, the anode 61 is connected to the substrate structure 3, the anode 61 is a transparent electrode, and the substrate of the substrate structure 3 is made of a transparent material to form a bottom emission type organic electroluminescent module in which the surface of the anode 61 serves as a light-outputting surface. FIG. 5 illustrates still another example of the first preferred embodiment of the series-connected organic electroluminescent module of the present invention. In this example, the cathode 62 is connected to the substrate structure 3, the cathode 62 is a transparent electrode, and a substrate of the substrate structure 3 is made of a transparent material to form a reverse arranged bottom emission type organic electroluminescent module in which the surface of the cathode 62 serves as a light-outputting surface. Alternatively, as shown in FIG. 6, the cathode 62 may be connected to the substrate structure 3 and the anode 61 is a transparent electrode to form a reverse arranged top emission type organic electroluminescent module in which the surface of the anode 61 serves as a light-outputting surface. In addition, the abovementioned electrodes may be made of a conductive metal, an oxide metal or a conductive polymer. It is understood that various lighting modes may be obtained depending on the manner of connections and the light transmissive properties of the anode 61, the cathode 62 and the substrate structure 3, as is well known in the art.

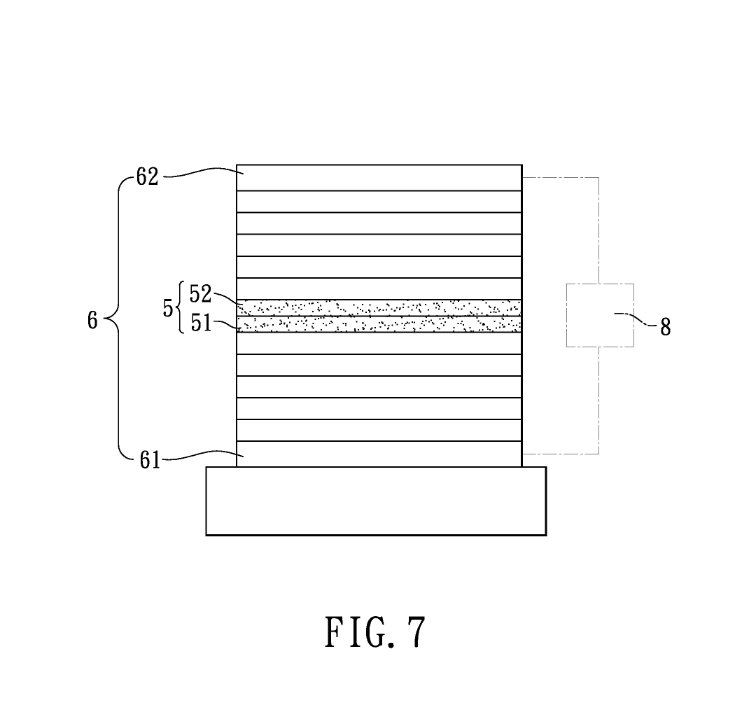

Referring to FIG. 7, the charge-generating body 5 includes an n-type material layer 51 that is proximate to the anode 61 of the electrode unit 6, and a p-type material layer 52 that is proximate to the cathode 62 of the electrode unit 6. Therefore, the charge-generating body 5 can generate more effectively the electrons and holes.

Preferably, the p-type material layer 52 and the n-type material layer 51 are made of a material capable of absorbing visible light that has a wavelength ranging from 380 nm to 780 nm. The p-type material layer 52 is made of a material selected from the group consisting of TiOPC (titanium oxide phthalocyanine), ZnPc (zinc phthalocyanine), MePTC (N,N′-dimethyl-3,4,9,10-perylene dicarboximide), F₁₆CuPc (copper(II) 1, 2, 3, 4, 8, 9, 10, 11, 15, 16, 17, 18, 22, 23, 24, 25-hexadecafluoro-29H,31H-phthalocyanine), and combinations thereof.

Preferably, the n-type material layer 51 is made of a material selected from the group consisting of C60, PC₆₁BM ([6,6]-phenyl-C61 butyric acid methyl ester) and isomers thereof, PTCBi (3,4,9,10-perylenetetracarboxylic-bis-benzimidazole), PC71BM ([6,6]-phenyl C71 butyric acid methyl ester) and isomers thereof, C70, ICMA (indene-C60 mono-adduct), indene-C60 bis-adduct, PC71HM ([6,6]-Phenyl-C71 hexnoic acid methyl ester) and isomers thereof, PTCDi (3,4,9,10-perylenetetracarboxylic acid diimide), PDCDT (N,N′-bis(2,5-di-tert-butylphenyl)-3,4,9,10-perylene-dicarboximide acid diimide), and combinations thereof.

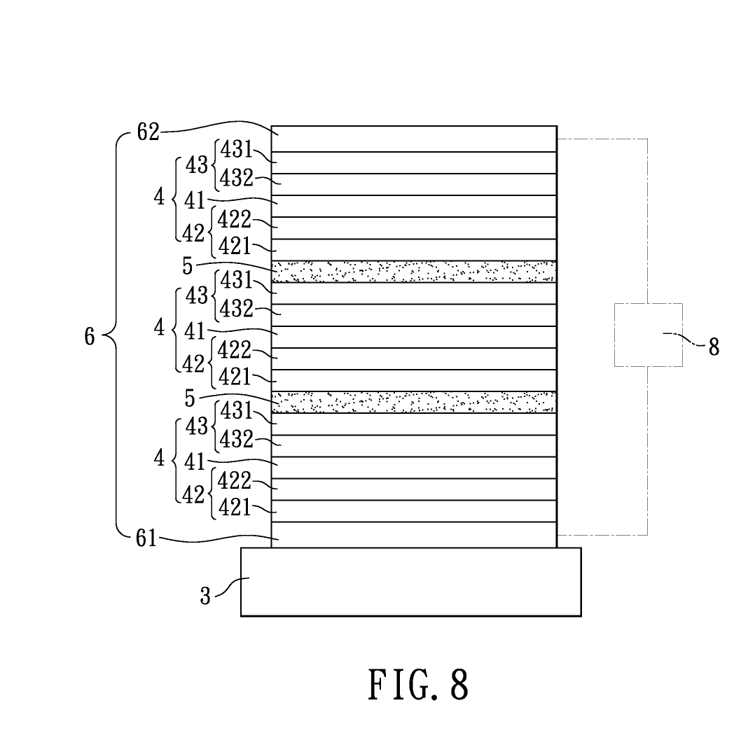

FIG. 8 illustrates a second preferred embodiment of a series-connected organic electroluminescent module of the present invention. The series-connected organic electroluminescent module of the second preferred embodiment is similar to that of the first preferred embodiment except that the series-connected organic electroluminescent module of the second preferred embodiment comprises three electroluminescent bodies 4 and two charge-generating bodies 5.

Each of the charge-generating bodies 5 is disposed to connect respective adjacent two of the electroluminescent bodies 4 so as to form a series-connection of the electroluminescent bodies 4 and the charge-generating bodies 5. The anode 61 is connected to the hole injecting layer 421 of the electroluminescent body 4 located at one of the opposite terminals of the series-connection, while the cathode 62 is connected to the electron injecting layer 431 of the electroluminescent body 4 located at the other one of the opposite terminals of the series-connection.

When the charge-generating bodies 5 are irradiated, each of the charge-generating bodies 5 is excited to generate electron-hole pairs, wherein the electrons are moved toward the anode 61, and then moved into the organic light-emitting layers 41 of the electroluminescent bodies 4 that are proximate to the charge-generating bodies 5, while the holes are moved toward the cathode 62, and then moved into the organic light-emitting layers 41 of the electroluminescent bodies 4 that are proximate to the charge-generating bodies 5. At this time, holes from the external driving current source 8 are introduced into the organic light-emitting layer 41 of the electroluminescent body 4 that is proximate to the anode 61 through the anode 61, and electrons from the external driving current source 8 are introduced into the organic light-emitting layer 41 of the electroluminescent body 4 that is proximate to the cathode 62 from the cathode 62.

The electroluminescent body 4 that is connected to the anode 61 receives the holes from the anode 61 and the electrons from the charge-generating body 5 that is proximate to the anode 61 so that the holes and the electrons are recombined to release light energy to emit light externally. The electroluminescent body 4 that is disposed between the charge-generating bodies 5 receives the holes formed in the charge-generating body 5 that is proximate to the anode 61 and the electrons formed in the charge-generating body 5 that is proximate to the cathode 62, respectively, so that the holes and the electrons are recombined to release light energy to emit light externally. The electroluminescent body 4 that is connected to the cathode 62 receives the electrons from the cathode 62 and the holes from the charge-generating body 5 that is proximate to the cathode 62 so that the holes and the electrons are recombined to release light energy to emit light externally.

When the three electroluminescent bodies 4 are connected in series and are applied with a predetermined driving voltage that is the same as that of the first preferred embodiment, because more charge-generating bodies 5 are provided, more electrons and holes may be formed. Therefore, as compared to the series-connected organic electroluminescent module of the first preferred embodiment, more light may be generated due to the recombination of the electrons and holes in the organic light-emitting layers 41 in this embodiment, thereby obtaining a higher luminance at a predetermined driving voltage. That is, the driving voltage can be further reduced when light of a predetermined luminance is desired to be emitted externally.

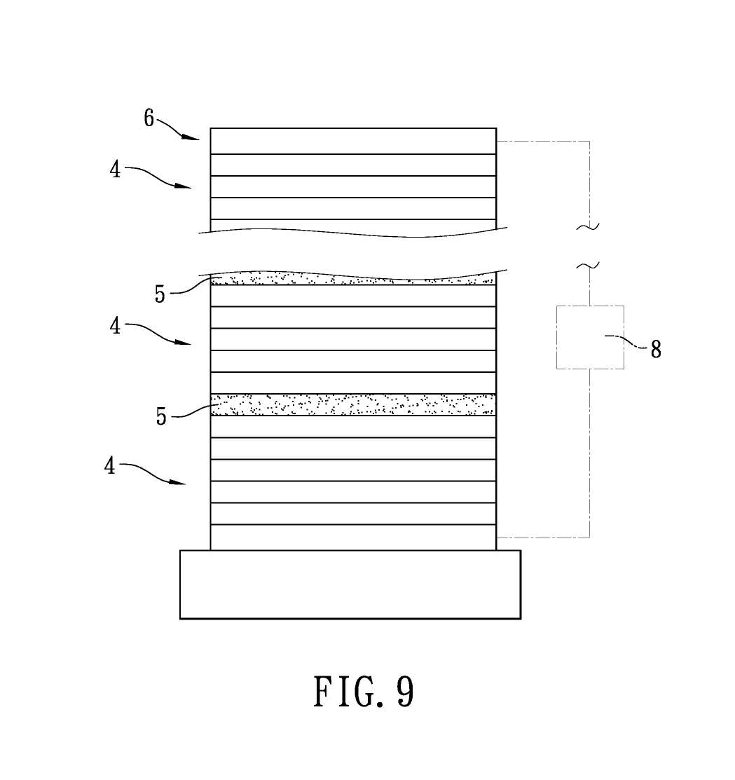

Referring to FIG. 9, it is noted that the number of the electroluminescent bodies 4 of the organic electroluminescent module of the present invention is not limited to 2 or 3. The organic electroluminescent module may include a plurality of electroluminescent bodies 4 and a plurality of charge-generating bodies 5 each of which is disposed between adjacent two of the electroluminescent bodies 4. When the number of the electroluminescent bodies 4 is n which is a positive integer not less than 2, the number of the charge-generating bodies 5 is not greater than (n−1). Preferably, the number of the charge-generating bodies 5 is (n−1). In addition, the electrode unit 6 is connected respectively to two opposite terminals of the series-connection of the electroluminescent bodies 4 and the charge-generating bodies 5.

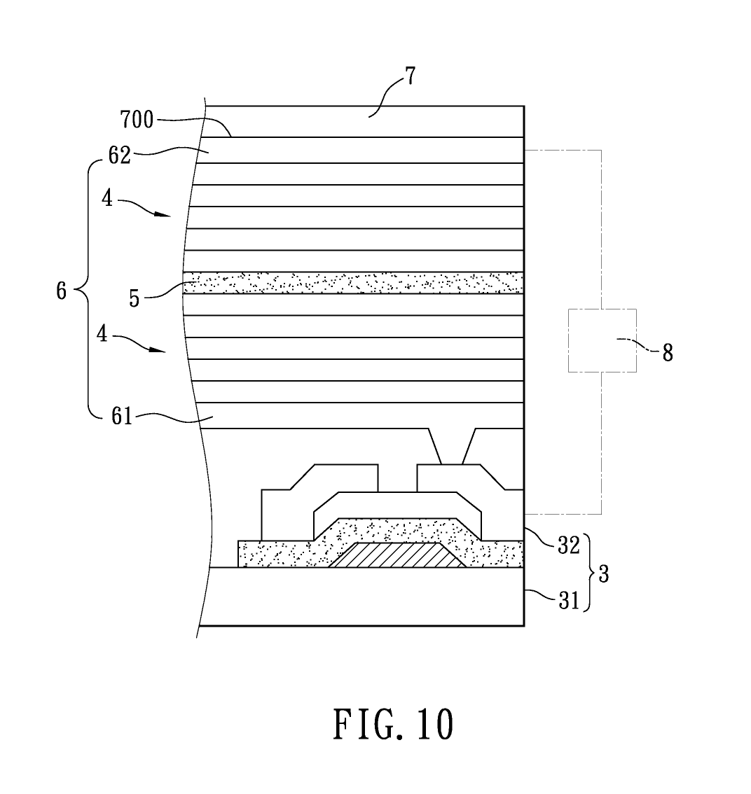

FIG. 10 illustrates a third preferred embodiment of a series-connected organic electroluminescent module of the present invention. The series-connected organic electroluminescent module of the third preferred embodiment is similar to that of the first preferred embodiment except that the series-connected organic electroluminescent module of the third preferred embodiment further comprises a filter sheet 7, and the substrate structure 3 includes a substrate 31 and a thin film transistor driving circuit 32 disposed on the substrate 31.

One of the anode 61 and the cathode 62 is electrically connected to the thin film transistor driving circuit 32 so that the electroluminescent bodies 4 can be driven to actuate. Therefore, the electroluminescent bodies 4 can be controlled to be in an ON or OFF state. In this embodiment, the anode 61 is connected to the substrate structure 3, and the cathode 62 is a transparent electrode. Thus, a top emission type organic electroluminescent module in which the surface of the cathode 62 serves as a light-outputting surface is formed.

The substrate 31 of the substrate structure 3 is a glass substrate or a flexible substrate, but is not limited thereto. In addition, the substrate 31 may be made of transparent or opaque material. When the anode 61 is connected to the substrate structure 3, the anode 61 is a transparent electrode, and the substrate 31 of the substrate structure 3 is made of a transparent material, a bottom emission type organic electroluminescent module in which the surface of the anode 61 serves as a light-outputting surface is formed. When the cathode 62 is connected to the substrate structure 3, the cathode 62 is a transparent electrode, and the substrate 31 of the substrate structure 3 is made of a transparent material, a reverse arranged bottom emission type organic electroluminescent module in which the surface of the cathode 62 serves as a light-outputting surface is formed. When the cathode 62 is connected to the substrate structure 3, and the anode 61 is a transparent electrode, a reverse arranged top emission type organic electroluminescent module in which the surface of the anode 61 serves as a light-outputting surface is formed. In addition, the abovementioned electrodes may be made of a conductive metal, an oxide metal or a conductive polymer.

The filter sheet 7 is disposed on the light-outputting surface 700 from which the light generated in the organic light-emitting layers 41 of the electroluminescent bodies 4 leaves the series-connected organic electroluminescent module. Therefore, after the light emitted from the electroluminescent bodies 4 passes through the filter sheet 7, a mixed light may be emitted externally. The mixed light may have a wavelength range that is different from that of the light emitted from the electroluminescent bodies 4. More specifically, in the bottom emission type organic electroluminescent module, the filter sheet 7 may disposed between the series-connection of the electroluminescent bodies 4 and the charge-generating bodies 5 and the thin film transistor driving circuit 32. In addition, in the top emission type organic electroluminescent module, the filter sheet 7 may disposed on the series-connection of the electroluminescent bodies 4 and the charge-generating bodies 5 while the series-connection of the electroluminescent bodies 4 and the charge-generating bodies 5 is disposed on the thin film transistor driving circuit 32.

It is noted that if applied to a display, a plurality of the series-connected organic electroluminescent modules of the third preferred embodiment may arranged in an array in combination with the filter sheet 7 that serves as a RGB or RGBW color filter in order to externally emit mixed lights of different wavelength ranges. Therefore, a predetermined image may be produced by virtue of the control of the thin film transistor driving circuit 32. Alternatively, the light emitting materials of the electroluminescent bodies 4 of the third preferred embodiment may be varied to emit lights of different wavelength ranges when receiving the electrons and holes. Therefore, the filter sheet that is used for changing the wavelength range of the light may be eliminated to reduce the manufacturing cost.

Furthermore, since the charge-generating body 5 may absorb an external light that irradiates the organic electroluminescent module, and also absorb the light that emits from the electroluminescent bodies 4 to the charge-generating body 5, when the series-connected organic electroluminescent module of the present invention is used as a display, the glare rate thereof can be reduced and the ambient contrast ratio can be significantly increased. That is, the luminance and the image quality provided by the series-connected organic electroluminescent module of the present invention will not be affected by ambient light.

To sum up, the charge-generating body 5 of the series-connected organic electroluminescent module of the present invention can generate electrons and holes while being irradiated, thereby increasing the amount of the electrons and holes in the organic light-emitting layers 41 of the electroluminescent bodies 4. Therefore, the light emitting efficiency can be effectively improved and the driving voltage can be reduced. In addition, if the series-connected organic electroluminescent module of the present invention is used in a display application, not only can the driving voltage be reduced, but the glare rate of the light-outputting surface can also be effectively reduced and the ambient contrast ratio can also be increased because the charge-generating body 5 may absorb the external light and the light that emits from the organic light-emitting layer 41 in a direction distal from the light-outputting surface. Therefore, the display quality can be improved.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A series-connected organic electroluminescent module, comprising:
a plurality of electroluminescent bodies each including an organic light-emitting layer;
at least one charge-generating body capable of generating holes and electrons while being irradiated, and disposed to connect respective adjacent two of said electroluminescent bodies so as to form a series-connection of said electroluminescent bodies and said at least one charge-generating body; and
an electrode unit including an anode and a cathode that are respectively electrically connected to two outermost ones of said electroluminescent bodies which are respectively disposed on two opposite terminals of said series-connection of said electroluminescent bodies and said at least one charge-generating body.

2. The series-connected organic electroluminescent module of claim 1, wherein said charge-generating body is capable of generating holes and electrons while receiving electricity.

3. The series-connected organic electroluminescent module of claim 1, wherein the number of said electroluminescent bodies is n which is a positive integer not less than 2, and the number of said at least one charge-generating body is (n−1).

4. The series-connected organic electroluminescent module of claim 1, wherein said charge-generating body includes an n-type material layer that is proximate to said anode, and a p-type material layer that is proximate to said cathode.

5. The series-connected organic electroluminescent module of claim 4, wherein said n-type and p-type material layers are made of a material capable of absorbing visible light.

6. The series-connected organic electroluminescent module of claim 4, wherein said p-type material layer is made of a material selected from the group consisting of titanium oxide phthalocyanine, zinc phthalocyanine, N,N′-dimethyl-3,4,9,10-perylene dicarboximide, copper(II) 1,2,3,4,8,9,10,11,15,16,17,18,22,23,24,25-hexade cafluoro-29H,31H-phthalocyanine, and combinations thereof.

7. The series-connected organic electroluminescent module of claim 4, wherein said n-type material layer is made of a material selected from the group consisting of C60, [6,6]-phenyl-C61 butyric acid methyl ester and isomers thereof, 3,4,9,10-perylenetetracarboxylic-bis-benzimidazole, [6,6]-phenyl C71 butyric acid methyl ester and isomers thereof, C70, indene-C60 mono-adduct, indene-C60 bis-adduct, [6,6]-Phenyl-C71 hexnoic acid methyl ester and isomers thereof, 3,4,9,10-perylenetetracarboxylic acid diimide, N,N′-bis(2,5-di-tert-butylphenyl)-3,4,9,10-perylene-dicarboximide acid diimide, and combinations thereof.

8. The series-connected organic electroluminescent module of claim 1, further comprising a substrate structure that includes a substrate and a thin film transistor driving circuit disposed on said substrate, one of said anode and said cathode being electrically connected to said thin film transistor driving circuit.

9. The series-connected organic electroluminescent module of claim 8, wherein said anode is connected to said substrate structure, said anode is a transparent electrode, and said substrate is made of a transparent material.

10. The series-connected organic electroluminescent module of claim 8, wherein said anode is connected to said substrate structure, and said cathode is a transparent electrode.

11. The series-connected organic electroluminescent module of claim 8, wherein said cathode is connected to said substrate structure, said cathode is a transparent electrode, and said substrate is made of a transparent material.

12. The series-connected organic electroluminescent module of claim 8, wherein said cathode is connected to said substrate structure, and said anode is a transparent electrode.

13. The series-connected organic electroluminescent module of claim 8, wherein said substrate is made of a flexible material.

14. The series-connected organic electroluminescent module of claim 1, further comprising a light-outputting surface from which light generated in said organic light-emitting layer leaves said series-connected organic electroluminescent module, and a filter sheet disposed on said light-outputting surface.

15. The series-connected organic electroluminescent module of claim 1, wherein each of said electroluminescent bodies further includes a hole transporting unit connected to a first surface of said organic light-emitting layer, and an electron transporting unit connected to a second surface of said organic light-emitting layer opposite to said first surface.

16. The series-connected organic electroluminescent module of claim 15, wherein:
said hole transporting unit includes a hole transporting layer connected to said organic light-emitting layer, and a hole injecting layer connected to said hole transporting layer; and
said electron transporting unit includes an electron transporting layer connected to said organic light-emitting layer, and an electron injecting layer connected to said electron transporting layer.

17. A series-connected organic electroluminescent module, comprising:
a plurality of electroluminescent bodies each including an organic light-emitting layer capable of emitting light while receiving holes and electrons;
at least one charge-generating body including an n-type material layer and a p-type material layer, said charge-generating body being disposed to connect respective adjacent two of said electroluminescent bodies so as to form a series-connection of said electroluminescent bodies and said at least one charge-generating body, said n-type and p-type material layers being made of a material capable of absorbing visible light; and
an electrode unit including an anode and a cathode that are respectively electrically connected to two outermost ones of said electroluminescent bodies which are respectively disposed on two opposite terminals of said series-connection of said electroluminescent bodies and said at least one charge-generating body;
wherein said charge-generating body is capable of generating holes and electrons while being irradiated.

18. The series-connected organic electroluminescent module of claim 17, wherein said p-type material layer is made of a material selected from the group consisting of titanium oxide phthalocyanine, zinc phthalocyanine, N,N′-dimethyl-3,4,9,10-perylene dicarboximide, copper(II) 1,2,3,4,8,9,10,11,15,16,17,18,22,23,24,25-hexade cafluoro-29H,31H-phthalocyanine, and combinations thereof.

19. The series-connected organic electroluminescent module of claim 17, wherein said n-type material layer is made of a material selected from the group consisting of C60, [6,6]-phenyl-C61 butyric acid methyl ester and isomers thereof, 3,4,9,10-perylenetetracarboxylic-bis-benzimidazole, [6,6]-phenyl C71 butyric acid methyl ester and isomers thereof, C70, indene-C60 mono-adduct, indene-C60 bis-adduct, [6,6]-Phenyl-C71 hexnoic acid methyl ester and isomers thereof, 3,4,9,10-perylenetetracarboxylic acid diimide, N,N′-bis(2,5-di-tert-butylphenyl)-3,4,9,10-perylene-dicarboximide acid diimide, and combinations thereof.

20. A display device comprising the series-connected organic electroluminescent module of claim 1.
